(19) United States
(12) Patent Application Publication
(10) Pub. No.: US 2026/0181870 A1
(43) Pub. Date: Jun. 25, 2026

(54) SEMICONDUCTOR STRUCTURE, MANUFACTURE METHOD THEREOF, AND MEMORY SYSTEM

(71) Applicant: Yangtze Memory Technologies Co., Ltd., Wuhan (CN)

(72) Inventors: Hao ZHANG, Wuhan (CN); Zhaoyun TANG, Wuhan (CN)

(21) Appl. No.: 19/413,465

(22) Filed: Dec. 9, 2025

(30) Foreign Application Priority Data
Dec. 25, 2024 (CN) 202411932358.8

(51) Int. Cl. H10B 12/00; H10D 62/10; H10D 64/27

(52) U.S. Cl. CPC H10B 12/34; H10B 12/053; H10B 12/318; H10B 12/482; H10D 62/124; H10D 64/518

(57) ABSTRACT

Semiconductor structures, manufacture methods thereof, and memory systems are provided. In one aspect, a semiconductor structure includes a semiconductor pillar and a bit line. The semiconductor pillar extends in a first direction and includes a first sub-semiconductor pillar and a second sub-semiconductor pillar stacked along the first direction. A width of the first sub-semiconductor pillar in a second direction is greater than a width of the second sub-semiconductor pillar in the second direction, the first direction intersecting with the second direction. The bit line is disposed on a side of the second sub-semiconductor pillar away from the first sub-semiconductor pillar along the first direction.

### CROSS-REFERENCE TO RELATED APPLICATIONS

This application claims the benefit of priority to Chinese Patent Application No. 202411932358.8, filed on Dec. 25, 2024, the disclosure of which is hereby incorporated by reference in its entirety.

### TECHNICAL FIELD

The present disclosure relates to the field of semiconductor chip technologies, and in particular, to a semiconductor structure, a manufacture method thereof, and a memory system.

### BACKGROUND

With the improvement of process technology, circuit design, and manufacture processes, dynamic random access memory (DRAM) is scaled to smaller sizes. However, as the feature size of memory cells within a memory approaches a lower limit, planar processes and fabrication techniques become challenging and costly, causing the density of memory cells to approach an upper limit.

Therefore, how to further achieve DRAM miniaturization becomes a technical problem that is difficult for those skilled in the art to solve.

### SUMMARY

Examples of the present disclosure provide a semiconductor structure, a manufacture method thereof, and a memory system. The semiconductor structure can be applied to, for example, a dynamic random access memory to implement data reading and writing operations.

The examples of the present disclosure adopt the following technical solutions.

In one aspect, examples of the present disclosure provide a semiconductor structure. The semiconductor structure includes a semiconductor pillar and a bit line. The semiconductor pillar extends along a first direction, and the semiconductor pillar includes a first sub-semiconductor pillar and a second sub-semiconductor pillar stacked along the first direction. A width of the first sub-semiconductor pillar in a second direction is greater than a width of the second sub-semiconductor pillar in the second direction, and the first direction intersects with the second direction. The bit line is disposed on a side of the second sub-semiconductor pillar away from the first sub-semiconductor pillar.

In some examples, the semiconductor structure further includes a first isolation structure. The first isolation structure is disposed on a side of the semiconductor pillar along the second direction. The first sub-semiconductor pillar includes a first surface and a second surface disposed opposite to each other along the second direction, and the first surface is closer to the first isolation structure than the second surface. The second sub-semiconductor pillar includes a third surface and a fourth surface disposed opposite to each other along the second direction, and the third surface is closer to the first isolation structure than the fourth surface. In the second direction, a distance between the second surface and the first isolation structure is greater than a distance between the fourth surface and the first isolation structure.

In some examples, a width of the second sub-semiconductor pillar in the second direction is greater than or equal to 5 nm and less than or equal to 10 nm.

In some examples, a ratio of the width of the first sub-semiconductor pillar in the second direction to the width of the second sub-semiconductor pillar in the second direction is greater than or equal to 1.2 and less than or equal to 2.2.

In some examples, the semiconductor structure further includes a gate. The gate is disposed on a side of the second sub-semiconductor pillar away from the first isolation structure along the second direction.

In some examples, the first sub-semiconductor pillar further includes a fifth surface and a sixth surface disposed opposite to each other along the first direction, and the fifth surface is closer to the second sub-semiconductor pillar than the sixth surface. The gate includes a first sub-portion and a second sub-portion connected to the first sub-portion, the first sub-portion is disposed on a side of the second sub-semiconductor pillar away from the first isolation structure along the second direction, and the second sub-portion is disposed on a side of the fifth surface along the first direction.

In some examples, the semiconductor pillar includes a plurality of semiconductor pillars arranged in multiple rows and multiple columns. The second surfaces of a column of the first sub-semiconductor pillars are disposed on a same side of the column of the first sub-semiconductor pillars in the second direction. In two adjacent columns of the first sub-semiconductor pillars, the second surfaces of a first column of the first sub-semiconductor pillars is disposed on a side of the first column of the first sub-semiconductor pillars in the second direction, and the second surfaces of a second column of the first sub-semiconductor pillars is disposed on the other side of the second column of the first sub-semiconductor pillars in the second direction.

In some examples, the gate includes a plurality of gates arranged in multiple rows and multiple columns. One gate is correspondingly disposed on a side of one semiconductor pillar in the second direction, and a column of the gates are disposed on the same side of a column of the semiconductor pillars in the second direction. A row of the semiconductor pillars includes adjacent first semiconductor pillar and second semiconductor pillar, the first semiconductor pillar and the second semiconductor pillar are arranged at intervals in the second direction, and the gate corresponding to the first semiconductor pillar and the gate corresponding to the second semiconductor pillar are disposed between the first semiconductor pillar and the second semiconductor pillar. The first isolation structure is disposed on a side of the first semiconductor pillar away from the gate along the second direction.

In some examples, in the second direction, a distance between the first sub-semiconductor pillar of the first semiconductor pillar and the first sub-semiconductor pillar of the second semiconductor pillar is the same as a width of the first isolation structure in the second direction.

In some examples, the semiconductor structure further includes an insulating filling structure. The insulating filling structure is disposed between the first semiconductor pillar and the second semiconductor pillar, and the gate corresponding to the first semiconductor pillar and the gate corresponding to the second semiconductor pillar are both embedded in the insulating filling structure.

In some examples, the insulating fill structure includes an air gap disposed between the gate corresponding to the first semiconductor pillar and the gate corresponding to the second semiconductor pillar.

In some examples, the semiconductor structure further includes a first dielectric layer. The first dielectric layer is disposed on a side of the first sub-semiconductor pillar away from the first isolation structure along the second direction.

In some examples, the semiconductor structure further includes a connection structure. The connection structure is disposed on a side of the semiconductor pillar away from the bit line along the first direction, and the connection structure is connected to an end of the first sub-semiconductor pillar away from the second sub-semiconductor pillar.

In some examples, the semiconductor structure further includes a capacitor structure layer. The capacitor structure layer is disposed on a side of the connection structure away from the semiconductor pillar along the first direction. The capacitor structure layer includes a capacitor unit, and the capacitor unit is connected to an end of the connection structure away from the first sub-semiconductor pillar.

In another aspect, examples of the present disclosure provide a manufacture method of a semiconductor structure, including: forming an initial semiconductor pillar; removing a portion of the initial semiconductor pillar to form a semiconductor pillar, wherein the semiconductor pillar extends along a first direction, and the semiconductor pillar includes a first sub-semiconductor pillar and a second sub-semiconductor pillar stacked along the first direction, and a width of the first sub-semiconductor pillar in a second direction is greater than a width of the second sub-semiconductor pillar in the second direction, the first direction intersecting with the second direction; and forming a bit line on a side of the second sub-semiconductor pillar away from the first sub-semiconductor pillar.

In some examples, removing a portion of the initial semiconductor pillar to form the semiconductor pillar includes: forming a sacrificial structure between two initial semiconductor pillars arranged at intervals along the second direction, the sacrificial structure and the two initial semiconductor pillars enclosing to form a first strip groove; forming a first dielectric layer in the first strip groove, the first dielectric layer covering the initial semiconductor pillar exposed by sidewalls of the first strip groove; removing the sacrificial structure through the first strip groove to form a second strip groove; and removing a portion of the initial semiconductor pillar through the second strip groove to form the semiconductor pillar and a third strip groove, wherein the portion of the semiconductor pillar covered by the first dielectric layer forms the first sub-semiconductor pillar, and the portion of the semiconductor pillar exposed by the third strip groove forms the second sub-semiconductor pillar.

In some examples, the manufacture method of the semiconductor structure further includes: forming a gate on a side of the semiconductor pillar along the second direction through the third strip groove.

In some examples, forming the gate on the side of the semiconductor pillar along the second direction includes: forming a conductive layer in the third strip groove, the conductive layer covering a bottom and sidewalls of the third strip groove; and removing a portion of the conductive layer to form the gate and expose the first dielectric layer and the bottom of the third strip groove.

In some examples, the manufacture method of the semiconductor structure further includes: forming an insulating layer in the third strip groove, the insulating layer covering sidewalls of the semiconductor pillar exposed by the third strip groove and the bottom of the third strip groove; and removing the insulating layer covering the bottom of the third strip groove to form a gate dielectric layer.

In yet another aspect, examples of the present disclosure provide a memory system, including: a semiconductor structure and a controller. The semiconductor structure includes a semiconductor pillar and a bit line, the semiconductor pillar extends along a first direction, and the semiconductor pillar includes a first sub-semiconductor pillar and a second sub-semiconductor pillar stacked along the first direction. A width of the first sub-semiconductor pillar in a second direction is greater than a width of the second sub-semiconductor pillar in the second direction, and the first direction intersects with the second direction. The bit line is disposed on a side of the second sub-semiconductor pillar away from the first sub-semiconductor pillar. The controller is coupled to the semiconductor structure to control the semiconductor structure to store data.

### BRIEF DESCRIPTION OF DRAWINGS

In order to more clearly illustrate the technical solutions in the present disclosure, the drawings required to be used in some examples of the present disclosure will be briefly described below, it is obvious that the drawings in the following description are only the drawings of some examples of the present disclosure, and other drawings may also be obtained by those of ordinary skill in the art according to these drawings. In addition, the accompanying drawings in the following description may be considered as schematic diagrams, and are not intended to limit an actual size of a product, an actual process flow of a method, an actual time sequence of a signal, and the like.

FIG. 1 is a structural block diagram of an electronic device provided by some examples of the present disclosure;

FIG. 2 is a structural block diagram of a memory provided by some examples of the present disclosure;

FIG. 3 is a schematic structural diagram of a semiconductor structure provided by some examples of the present disclosure;

FIG. 4 is a schematic structural diagram of another semiconductor structure provided by some examples of the present disclosure;

FIG. 5 is a schematic structural diagram of another semiconductor structure provided by some examples of the present disclosure;

FIG. 6 is a flowchart of a manufacture method of a semiconductor structure provided by some examples of the present disclosure;

FIG. 7 is a flowchart of a manufacture method of an initial semiconductor pillar provided by some examples of the present disclosure;

FIG. 8 is a schematic structural diagram of a semiconductor structure corresponding to the manufacture method in FIG. 7;

FIG. 9 is a schematic structural diagram of another semiconductor structure corresponding to the manufacture method in FIG. 7;

FIG. 10 is a flowchart of a manufacture method of a semiconductor structure provided by some examples of the present disclosure;

FIG. 11 is a schematic structural diagram of a semiconductor structure corresponding to the manufacture method in FIG. 10;

FIG. 12 is a schematic structural diagram of another semiconductor structure corresponding to the manufacture method in FIG. 10;

FIG. 13 is a schematic structural diagram of yet another semiconductor structure corresponding to the manufacture method in FIG. 10;

FIG. 14 is a schematic structural diagram of yet another semiconductor structure corresponding to the manufacture method in FIG. 10;

FIG. 15 is a schematic structural diagram of yet another semiconductor structure corresponding to the manufacture method in FIG. 10;

FIG. 16 is a schematic structural diagram of yet another semiconductor structure corresponding to the manufacture method in FIG. 10;

FIG. 17 is a flowchart of a manufacture method for a gate provided by some examples of the present disclosure;

FIG. 18 is a schematic structural diagram of a semiconductor structure corresponding to the manufacture method in FIG. 17;

FIG. 19 is a schematic structural diagram of another semiconductor structure corresponding to the manufacture method in FIG. 17;

FIG. 20 is a flowchart of another manufacture method of a semiconductor structure provided by some examples of the present disclosure.

### DETAILED DESCRIPTION

The technical solutions in some examples of the present disclosure will be clearly and completely described below with reference to the accompanying drawings, and it is apparent that the described examples are only a part of the examples of the present disclosure rather than all of the examples. All other examples obtained by a person of ordinary skill in the art based on the examples of the present disclosure shall fall within the protection scope of the present disclosure.

Unless the context requires otherwise, throughout the specification and claims, the term “comprise” is to be construed in an open, inclusive sense, that is as “including, but not limited to.” In the description of the specification, the terms such as “one example”, “some examples”, “exemplary example”, “exemplarily” or “some examples” are intended to indicate that particular features, structures, materials or characteristics related to the example or implementation are included in at least one example or implementation of the present disclosure. Schematic representations of the above terms do not necessarily refer to the same example or implementation. In addition, the particular features, structures, materials or characteristics may be included in any one or more examples or implementations in any suitable manner.

The following terms “first” and “second” are merely intended for a purpose of description, and shall not be understood as indicating or implying relative importance or implicitly indicating a quantity of the indicated technical features. Thus, features defined as “first” and “second” may explicitly or implicitly include one or more of the features. In the description of the examples of the present disclosure, unless otherwise stated, “a plurality of” means two or more.

In the description of some examples, the terms “coupled” and “connected” and derivatives thereof may be used. For example, the term “connected” may be used in the description of some examples to indicate that two or more components are in direct physical or electrical contact with each other. For another example, the term “coupled” may be used in the description of some examples to indicate that two or more components are in direct physical or electrical contact. The term “coupled,” however, may also mean that two or more components are not in direct contact with each other, but yet still co-operate or interact with each other. The examples disclosed herein are not necessarily limited to the contents herein.

Example implementations are described herein with reference to cross-section views and/or plan views as idealized example drawings. In the drawings, the thicknesses of layers and regions may be exaggerated for clarity. As such, variations from the shapes of the illustrations as a result, for example, of manufacture techniques and/or tolerances, are to be expected. Thus, example implementations should not be construed as limited to the shapes of regions illustrated herein, but are to include deviations in shapes that result, for example, from manufacture. For example, an etched region shown as a rectangle will typically have curved features. Thus, the regions illustrated in the figures are schematic in nature and their shapes are not intended to illustrate an actual shape of a region of a device and are not intended to limit the scope of the example implementations.

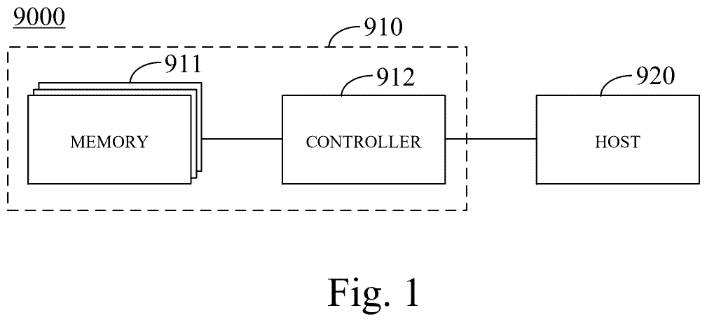

FIG. 1 is a structural block diagram of an electronic device 9000 provided by some examples of the present disclosure. The electronic device 9000 may be a mobile phone, a desktop computer, a laptop computer, a tablet computer, a vehicle computer, a gaming console, a printer, a positioning device, a wearable electronic device (e.g., a smart watch, a smart bracelet, smart glasses, etc.), a smart sensor, a virtual reality (VR) device, an augmented reality (AR) device, or any other suitable electronic device having a storage therein.

As shown in FIG. 1, the electronic device 9000 may include a memory system 910 and a host 920. The memory system 910 may be integrated into various types of storage devices, for example, a memory card. The memory card includes any one of a PC card (PCMCIA, Personal Computer Memory Card International Association), a compact flash (CF) card, a smart media (SM) card, a memory stick, a multimedia card (MMC), a secure digital memory card (SD), and a universal flash storage (UFS). That is, the memory system 910 may be applied to and packaged into different types of electronic products.

The host 920 may include a processor of the electronic device 9000, such as a central processing unit (CPU), or a system-on-chip (SoC), such as an application processor (AP). The host 920 may be configured to send data to or receive data from the memory.

In some examples, the memory system 910 may have one or more memories 911 and a controller 912. For example, the controller 912 may be configured to operate in a low duty cycle environment, such as an SD card, a CF card, a universal serial bus (USB) flash drive, or other media used in electronic devices such as personal computers, digital cameras, mobile phones, etc. Alternatively, in some other examples, the controller 912 is configured to operate in a high duty cycle environment SSD or eMMC for data storage and enterprise storage arrays of mobile devices such as smartphones, tablets, laptops, etc. Alternatively, in some examples, the controller 912 is coupled to the memory 911 and the host 920, and is configured to control data in the memory 911, while communicating with an external device (e.g., the host).

The memory 911 in the memory system 910 may include one or more memories 911, and in FIG. 1, three memories 911 are taken as an example for illustration. The controller 912 may manage data stored in each memory 911 and communicate with the host 920. The controller 912 may be configured to control operations of each memory 911, such as read, write, and refresh operations. The controller 912 may also be configured to manage various functions with respect to data stored or to be stored in each memory 911, including but not limited to refresh and timing control, command/request translation, buffering and scheduling, and power management. In some implementations, the controller 912 is further configured to determine the maximum memory capacity that the computer system can use, the number of memory banks, memory type and speed, data depth and data width of memory die, and other important parameters. Any other suitable functions may also be performed by the controller 912. The controller 912 may communicate with an external device (e.g., the host 920) according to a particular communication protocol. For example, the controller 912 may communicate with the external device through at least one of various interface protocols, such as a USB protocol, an MMC protocol, a peripheral component interconnection (PCI) protocol, a PCI Express (PCI-E) protocol, an advanced technology attachment (ATA) protocol, a serial ATA protocol, a parallel ATA protocol, a small computer small interface (SCSI) protocol, an enhanced small disk interface (ESDI) protocol, an integrated drive electronics (IDE) protocol, a Firewire protocol, etc.

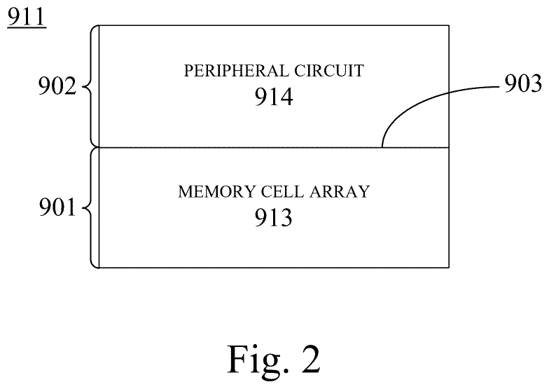

FIG. 2 is a structural block diagram of a memory 911 provided by some examples of the present disclosure. As shown in FIG. 2, memory 911 includes a memory cell array 913 and a peripheral circuit 914 for controlling the memory cell array 913. The peripheral circuit 914 may include any suitable digital, analog, and/or mixed-signal circuit for facilitating operation of the memory cell array 913. For example, the peripheral circuit 914 may include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portion of the functional circuit described above (e.g., a sub-circuit), or any active or passive component of the circuit (e.g., a transistor, diode, resistor, or capacitor).

Illustratively, the peripheral circuit 914 may be implemented by using a complementary metal-oxide-semiconductor (CMOS) technology, for example, a logic process (for example, a technology node of 90 nm, 65 nm, 60 nm, 45 nm, 32 nm, 28 nm, 22 nm, 20 nm, 16 nm, 14 nm, 10 nm, 7 nm, 5 nm, 3 nm, or 2 nm).

The memory cell array 913 and the peripheral circuit 914 may be arranged side by side in the same plane, for example, on the same wafer, that is, the memory cell array 913 and the peripheral circuit 914 may be located in the same semiconductor structure. The memory cell array 913 and the peripheral circuit 914 may also be formed on different wafers and bonded together in a face-to-face manner. As shown in FIG. 2, when the memory cell array 913 and the peripheral circuit 914 are formed on different wafers and bonded together in a face-to-face manner, the memory 911 may include a first semiconductor structure 901 and a second semiconductor structure 902, and a bonding interface 903 between the first semiconductor structure 901 and the second semiconductor structure 902. The first semiconductor structure 901 may include the memory cell array 913, and the second semiconductor structure 902 may include the peripheral circuit 914.

In some implementations, the memory cell array 913 may be an array of memory cells using vertical transistors as switch and select devices. For example, the memory cell array 913 may be a dynamic random access memory cell array. For ease of description, the DRAM cell array may be used to describe an example of the memory cell array 913 in the present disclosure. However, it should be understood that the memory cell array 913 is not limited to a DRAM cell array, and may also include, for example, any other suitable type of memory cell array 913 that may use vertical transistors as the switch and select devices, such as a PCM cell array, a static random access memory (SRAM) cell array, a ferroelectric random access memory (FRAM) cell array, a resistive memory cell array, a magnetic memory cell array, a spin transfer torque (STT) memory cell array, etc.

When the memory cell array 913 is a DRAM cell array, the memory cell therein is a DRAM cell, the DRAM cell includes a capacitor for storing data bit as positive or negative charge, and one or more transistor structures that control (e.g., switch and select) access to the DRAM cell. In some implementations, each DRAM cell is a 1T1C cell composed of one transistor structure and one capacitor. According to some implementations, the DRAM cell may be refreshed by the peripheral circuit 914 to retain data.

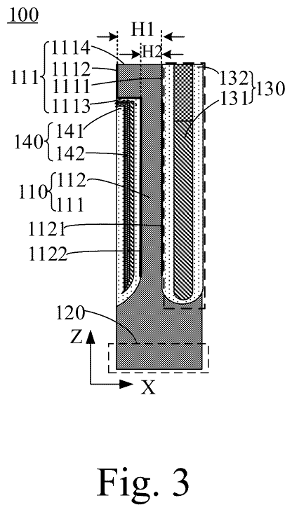

FIG. 3 is a schematic structural diagram of a semiconductor structure 100 provided by some examples of the present disclosure.

FIG. 3 is for illustrative purposes only, and may not necessarily reflect an actual device structure (e.g., interconnect) in practice.

As shown in FIG. 3, in some examples, the semiconductor structure 100 includes a semiconductor pillar 110 and a bit line 120. The semiconductor pillar 110 and the bit line 120 may be stacked in a first direction Z. Illustratively, the first direction Z may be a direction in which the first semiconductor structure 901 and the second semiconductor structure 902 shown in FIG. 2 are stacked.

The semiconductor pillar 110 extends along the first direction Z, and the semiconductor pillar 110 includes a first sub-semiconductor pillar 111 and a second sub-semiconductor pillar 112 stacked along the first direction Z. A width H1 of the first sub-semiconductor pillar 111 in a second direction X is greater than a width H2 of the second sub-semiconductor pillar 112 in the second direction X, and the bit line 120 is disposed on a side of the second sub-semiconductor pillar 112 away from the first sub-semiconductor pillar 111.

In a feasible implementation, the second sub-semiconductor pillar 112 may be used as a channel structure of a transistor structure manufactured subsequently. Based on this, in this example, by reducing the width H2 of the second sub-semiconductor pillar 112 in the second direction X, the thickness in the second direction X of the channel structure of the transistor structure manufactured based on the second sub-semiconductor pillar 112 can be reduced, thereby reducing the floating body effect of the transistor structure manufactured based on the second sub-semiconductor pillar 112 to a certain extent, thereby reducing the off-state leakage current of the transistor structure, and further prolonging the time of the DRAM cell where the transistor structure is located to retain data. In addition, by reducing the width H2 of the second sub-semiconductor pillar 112 in the second direction X, it is also beneficial to further reduce the size of the semiconductor structure 100.

In addition, in this example, by stacking the first sub-semiconductor pillar 111 on a side of the second sub-semiconductor pillar 112, the connection between the second sub-semiconductor pillar 112 and other device structures (e.g., a capacitor unit, etc.) may be enabled through the first sub-semiconductor pillar 111.

By setting the width H1 of the first sub-semiconductor pillar 111 in the second direction X to be greater than the width H2 of the second sub-semiconductor pillar 112 in the second direction X, the contact area between the first sub-semiconductor pillar 111 and other devices may be increased, thereby reducing the contact resistance between the first sub-semiconductor pillar 111 and other devices, and further reducing the device loss of the semiconductor structure 100. In addition, in this way, the first sub-semiconductor pillar 111 may also be used to reduce the difficulty of controlling the height of the gate in the first direction Z in the subsequent manufacture process of the gate, thereby improving the manufacture accuracy.

In a feasible implementation, the above described second direction X may intersect with the first direction Z.

Still referring to FIG. 3, in some examples, the width H2 of the second sub-semiconductor pillar 112 in the second direction X may be greater than or equal to 5 nm and less than or equal to 10 nm.

In some examples, the width H2 of the second sub-semiconductor pillar 112 in the second direction X is ≥5 nm, which can prevent the second sub-semiconductor pillar 112 from being too thin, for example, H2<5 nm. Illustratively, if the second sub-semiconductor pillar 112 is too thin, for example, H2<3 nm, the second sub-semiconductor pillar 112 will exist in the form of a thin film, thereby reducing the structural reliability of the second sub-semiconductor pillar 112. Thus, H2≥5 nm.

In this way, by increasing the value of H2, the reliability of the transistor structure and the semiconductor structure 100 subsequently manufactured based on the second sub-semiconductor pillar 112 can be improved while ensuring that the second sub-semiconductor pillar 112 meets the storage requirement.

In some other examples, H2≤10 nm, so that the second sub-semiconductor pillar 112 may be prevented from being too thick, for example, H2>10 nm. Illustratively, if the second sub-semiconductor pillar 112 is too thick, for example, H2>20 nm, the floating body effect of the transistor structure manufactured based on the second sub-semiconductor pillar 112 is relatively large, thereby causing a relatively large leakage current of the transistor structure, causing relatively high current consumption, and shortening the time of the DRAM cell where the transistor structure is located to retain data. Thus, H2≤10 nm.

Illustratively, the width H2 of the second sub-semiconductor pillar 112 in the second direction X may include any suitable width such as 5 nm, 5.5 nm, 6 nm, 6.5 nm, 7 nm, 7.5 nm, 8 nm, 8.5 nm, 9 nm, 9.5 nm, 10 nm, etc., which is not limited in the examples of the present disclosure.

Still referring to FIG. 3, in some examples, a ratio N of the width H1 of the first sub-semiconductor pillar 111 in the second direction X to the width H2 of the second sub-semiconductor pillar 112 in the second direction X is greater than or equal to 1.2 and less than or equal to 2.2.

In some examples, the ratio N of the width H1 of the first sub-semiconductor pillar 111 in the second direction X to the width H2 of the second sub-semiconductor pillar 112 in the second direction X being ≥1.2, may prevent the first sub-semiconductor pillar 111 from being too narrow, for example, N<1.2. Illustratively, if the first sub-semiconductor pillar 111 is too narrow, for example, N<1, the width H1 of the first sub-semiconductor pillar 111 in the second direction X would be close to the width H2 of the second sub-semiconductor pillar 112 in the second direction X, or, the width H1 of the first sub-semiconductor pillar 111 in the second direction X would be less than the width H2 of the second sub-semiconductor pillar 112 in the second direction X.

In this way, the arrangement of the first sub-semiconductor pillar 111 would fail to improve the electrical connection effect between the second sub-semiconductor pillar 112 and other devices, or even increase the contact resistance between the first sub-semiconductor pillar 111 and other device structures, thereby resulting in higher current consumption of the semiconductor structure 100.

Thus, N≥1.2. In this way, by increasing the value of N, on the premise of ensuring the electrical connection between the second sub-semiconductor pillar 112 and other device structures, the effect of the electrical connection between the second sub-semiconductor pillar 112 and other device structures achieved by the first sub-semiconductor pillar 111 can be improved, and the area of contact of the first sub-semiconductor pillar 111 with other device structures subsequently can be increased, thereby reducing the contact resistance between the first sub-semiconductor pillar 111 and other device structures, and reducing the device loss of the semiconductor structure 100.

In some other examples, N≤2.2, so that the first sub-semiconductor pillar 111 may be prevented from being too thick, for example, N>2.2. Illustratively, if the first sub-semiconductor pillar 111 is too thick, for example, N>3, then the first sub-semiconductor pillar 111 would occupy too much manufacture space in the second direction X, thereby increasing the size in the second direction X of the transistor structure manufactured based on the first sub-semiconductor pillar 111, which is not conducive to the miniaturization of the transistor structure or even the entire semiconductor structure 100 in size. Therefore, N≤2.2.

Illustratively, the ratio of the width H1 of the first sub-semiconductor pillar 111 in the second direction X to the width H2 of the second sub-semiconductor pillar 112 in the second direction X may include any suitable ratio such as 1.2, 1.3, 1.5, 1.6, 1.8, 2.0, 2.1, 2.2, which is not limited in the examples of the present disclosure.

Still referring to FIG. 3, in some examples, the semiconductor structure 100 further includes a first isolation structure 130. The first isolation structure 130 is disposed on a side of the semiconductor pillar 110 along the second direction X. In this way, in a case where the semiconductor pillar 110 includes a plurality of semiconductor pillars 110, the first isolation structure 130 may be used to isolate the semiconductor pillars 110 of two adjacent transistor structures, thereby improving the stability and reliability of the transistor structure.

In a feasible implementation, the first isolation structure 130 may include a first conductive structure 131 and an insulating structure 132. In this way, the first conductive structure 131 can be used to improve the effect of the first isolation structure 130 isolating the semiconductor pillars 110 of two adjacent columns of transistor structures.

The insulating structure 132 may be disposed around the first conductive structure 131, to enable the isolation between the first conductive structure 131 and two adjacent semiconductor pillars 110, thereby improving stability and reliability of the transistor structure.

Illustratively, the first conductive structure 131 may be made of a conductive material, for example, W, Co, Cu, Al, doped silicon, silicide, or any combination thereof. The material of the insulating structure 132 may include one or more of any suitable insulating material such as an oxide material (for example, silicon oxide), a nitride material (for example, silicon nitride), or an oxynitride material (for example, silicon oxynitride), which is not limited in the examples of the present disclosure. In this example, the conductive material of the first conductive structure 131 may be W, and the insulating material of the insulating structure 132 may be silicon oxide.

In addition, the first sub-semiconductor pillar 111 includes a first surface 1111 and a second surface 1112 disposed opposite to each other along the second direction X, and the first surface 1111 is closer to the first isolation structure 130 than the second surface 1112. The second sub-semiconductor pillar 112 includes a third surface 1121 and a fourth surface 1122 disposed opposite to each other along the second direction X, and the third surface 1121 is closer to the first isolation structure 130 than the fourth surface 1122.

Since the width H1 of the first sub-semiconductor pillar 111 in the second direction X is greater than the width H2 of the second sub-semiconductor pillar 112 in the second direction X, a distance between the second surface 1112 and the first isolation structure 130 in the second direction X is greater than a distance between the fourth surface 1122 and the first isolation structure 130 in the second direction X. That is, the second surface 1112 and the fourth surface 1122 are not coplanar in the first direction Z, and are staggered in the first direction Z.

Still referring to FIG. 3, in some examples, the semiconductor structure 100 further includes a gate 140. The gate 140 may be disposed on a side of the second sub-semiconductor pillar 112 away from the first isolation structure 130 along the second direction X.

In this example, by providing the gate 140 on the side of the second sub-semiconductor pillar 112 away from the first isolation structure 130, the transistor structure can be controlled to be on or off by using the gate 140, so that the DRAM cell where the transistor structure is located can perform read or write operations on the data.

In some examples, the gate 140 may employ a conductive material, such as W, Co, Cu, Al, doped silicon, silicide, or any combination thereof. In this example, the material of the gate 140 may employ tungsten.

In addition, in a feasible implementation, a layer of titanium nitride may be disposed on a side of the gate 140 close to the second sub-semiconductor pillar 112, to prevent the metal material of the gate 140 from diffusing. In addition, since titanium nitride has good adhesion, such arrangement is also beneficial to improve the stability of the structure of the gate 140.

Still referring to FIG. 3, in some examples, the first sub-semiconductor pillar 111 further includes a fifth surface 1113 and a sixth surface 1114 disposed opposite to each other along the first direction Z, and the fifth surface 1113 is closer to the second sub-semiconductor pillar 112 than the sixth surface 1114.

Since the width H1 of the first sub-semiconductor pillar 111 in the second direction X is greater than the width H2 of the second sub-semiconductor pillar 112 in the second direction X, the second surface 1112 and the fourth surface 1122 are staggered in the first direction Z, and based on this, in this example, the second surface 1112 may be connected to the fourth surface 1122 via the fifth surface 1113.

The gate 140 includes a first sub-portion 141 and a second sub-portion 142 connected to the first sub-portion 141, the first sub-portion 141 may be disposed on a side of the second sub-semiconductor pillar 112 away from the first isolation structure 130 along the second direction X, and the second sub-portion 142 may be disposed on a side of the fifth surface 1113 along the first direction Z.

With this arrangement, it is possible to increase a facing area between the entire gate 140 and the semiconductor pillar 110, thereby improving the control accuracy of the gate 140 over the transistor structure subsequently manufactured based on the semiconductor pillar 110.

Illustratively, the facing area may refer to an area where a projection of the first sub-portion 141 in the first direction Z overlaps with a projection of the fifth surface 1113 of the first sub-semiconductor pillar 111 in the first direction Z, and an area where a projection of the second sub-portion 142 in the second direction X overlaps with a projection of the second sub-semiconductor pillar 112 in the second direction X.

In addition, in this way, the leakage current of the transistor structure manufactured based on the semiconductor pillar 110 can be reduced by improving the control accuracy of the gate 140, thereby improving the time of the DRAM cell to retain data.

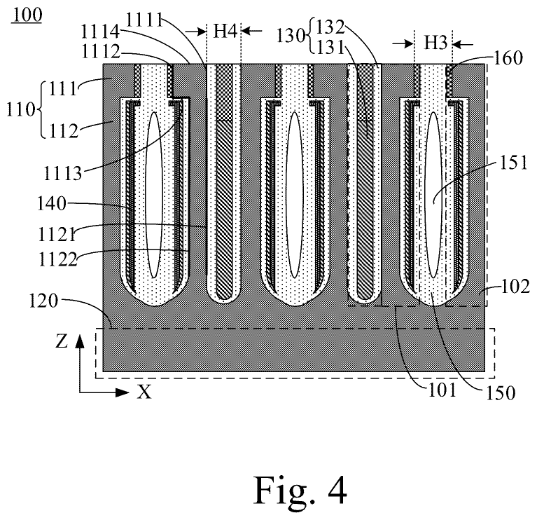

FIG. 4 is a schematic structural diagram of another semiconductor structure 100 provided by some examples of the present disclosure.

As shown in FIG. 4, in some examples, since the second surface 1112 of the first sub-semiconductor pillar 111 protrudes from the second sub-semiconductor pillar 112 correspondingly connected to the first sub-semiconductor pillar 111, in a case where the semiconductor pillar 110 includes a plurality of semiconductor pillars 110 arranged in multiple rows and multiple columns, the second surfaces 1112 of a column of the first sub-semiconductor pillars 111 are disposed on the same side of the column of the first sub-semiconductor pillars 111 in the second direction X.

In this way, the second surfaces 1112 of a column of the first sub-semiconductor pillars 111 may be made to protrude from the same side of a column of the second sub-semiconductor pillars 112 correspondingly connected to the column of the first sub-semiconductor pillars 111, thereby reducing the difficulty of the manufacture process of the first sub-semiconductor pillars 111 and the second sub-semiconductor pillars 112 in the process of manufacturing the semiconductor structure, and further reducing the difficulty of the manufacture process of the entire semiconductor structure 100, thereby improving the manufacturing efficiency of the semiconductor structure 100.

In addition, in this way, the semiconductor structure 100 may be simplified, so that the further miniaturization of the semiconductor structure 100 in size may be achieved.

Still referring to FIG. 4, in some examples, in a scenario in which the semiconductor pillar 110 includes a plurality of semiconductor pillars 110, the gate 140 may also include a plurality of gates 140, and the plurality of gates 140 may also be arranged in multiple rows and multiple columns. One gate 140 is correspondingly disposed on a side of one semiconductor pillar 110 in the second direction X, and a column of the gates 140 are disposed on the same side of a column of the semiconductor pillars 110 in the second direction X.

Illustratively, in this example, a combination of the first semiconductor pillars 101 and the second semiconductor pillars 102 adjacent to each other in a row of the semiconductor pillars 110 is taken as a minimum constituent unit. In this scenario, a row of the semiconductor pillars 110 may include a plurality of minimum constituent units disposed along the second direction X. The first semiconductor pillar 101 and the second semiconductor pillar 102 may be arranged at intervals along the second direction X, and the gate 140 corresponding to the first semiconductor pillar 101 and the gate 140 corresponding to the second semiconductor pillar 102 may be disposed between the first semiconductor pillar 101 and the second semiconductor pillar 102. The first isolation structure 130 may be disposed on a side of the first semiconductor pillar 101 away from the gate 140 along the second direction X.

In this way, in the manufacture method of the semiconductor structure 100, the gate 140 corresponding to the first semiconductor pillar 101 and the gate 140 corresponding to the second semiconductor pillar 102 may be manufactured in the same manufacture process, thereby simplifying the manufacture process of the gate 140 and reducing the difficulty of manufacturing the gate 140.

In addition, in a scenario in which the semiconductor pillar 110 includes a plurality of semiconductor pillars 110, the gates 140 of a column of the first semiconductor pillar 101 and the gates 140 of a column of the second semiconductor pillar 102 may be obtained in a same manufacture process, and the gates 140 of the column of the first semiconductor pillar 101 may be an integral structure, and the gates 140 of the column of the second semiconductor pillar 102 may also be an integral structure. For example, in a case that a column of gates 140 is an integral structure, the column of gate 140 may constitute a word line.

In this way, a column of transistor structures can be selected by controlling a word line formed by a column of gates 140, and on and off of a single transistor structure can be controlled in cooperation with the bit line 120, so that a single DRAM cell can read or write data.

In addition, based on the foregoing example, since the gate 140 may be disposed on the side of the second sub-semiconductor pillar 112 close to the second surface 1112 of the first sub-semiconductor pillar 111, in two adjacent columns of the first sub-semiconductor pillars 111 (for example, the first column of the first sub-semiconductor pillars 111 and the second column of the first sub-semiconductor pillars 111), the second surfaces 1112 of the first column of the first sub-semiconductor pillars 111 are disposed on a side of the first column of the first sub-semiconductor pillars 111 in the second direction X, and the second surfaces 1112 of the second column of the first sub-semiconductor pillars 111 are disposed on the other side of the second column of the first sub-semiconductor pillars 111 in the second direction X.

In some examples, when the plurality of transistor structures in the DRAM cell array are arranged in multiple rows and multiple columns, in order to further reduce the size of the DRAM cell array, the arrangement of the semiconductor pillars of the plurality of transistor structures in the same row of DRAM cells is mostly non-uniform. Illustratively, based on the foregoing description on the semiconductor pillars arranged in multiple rows and multiple columns, the size of the DRAM cell array can be further reduced by reducing the size of the first isolation structure 130 in the second direction X. That is, the width H4 of the first isolation structure 130 in the second direction X is less than the distance H3 between the first sub-semiconductor pillar 111 of the first semiconductor pillar 101 and the first sub-semiconductor pillar 111 of the second semiconductor pillar 102.

However, when the DRAM cell array is formed, the plurality of capacitor units docked with the semiconductor pillars arranged in multiple rows and multiple columns are mostly 6F², where F is the minimum process size of the DRAM cell. Based on this, the plurality of capacitor units of 6F² and the plurality of semiconductor pillars need to be connected through connection structures. However, the connection structures are mostly uniformly arranged, so when the plurality of connection structures are docked with the plurality of semiconductor pillars, since the arrangement of the semiconductor pillars of a row of transistor structures is non-uniform, each connection structure and the docked semiconductor pillar are connected by an offset connection. That is, in the first direction, the connection structure is disposed toward a side of the semiconductor pillar in the second direction.

In this way, the effective contact area between each connection structure and the docked semiconductor pillar is reduced, thereby causing an increase in the contact resistance between the connection structure and the docked semiconductor pillar, and further increasing the device loss of the semiconductor structure.

Based on this, referring to FIG. 4, in some examples, in the second direction X, the distance H3 between the first sub-semiconductor pillar 111 of the first semiconductor pillar 101 and the first sub-semiconductor pillar 111 of the second semiconductor pillar 102 is the same as the width H4 of the first isolation structure 130 in the second direction X.

In this way, the arrangement of the first sub-semiconductor pillars 111 of a row of semiconductor pillars may be made non-uniform, so that when the first sub-semiconductor pillars 111 are subsequently docked with a row of uniformly arranged connection structures, the degree of offset between each connection structure and its corresponding first sub-semiconductor pillar 111 can be reduced, thereby increasing the effective contact area between the connection structure and its docked first sub-semiconductor pillar 111, thereby reducing the contact resistance between the connection structure and its docked semiconductor pillar, and further reducing the device loss of the semiconductor structure.

Still referring to FIG. 4, in some examples, the semiconductor structure further includes an insulating filling structure 150. The insulating filling structure 150 is disposed between the first semiconductor pillar 101 and the second semiconductor pillar 102, and the gate 140 corresponding to the first semiconductor pillar 101 and the gate 140 corresponding to the second semiconductor pillar 102 are both embedded in the insulating filling structure 150.

In this example, by providing the insulating filling structure 150 between the first semiconductor pillar 101 and the second semiconductor pillar 102, the isolation between the first semiconductor pillar 101 and the second semiconductor pillar 102 can be achieved, and by embedding the gate 140 corresponding to the first semiconductor pillar 101 and the gate 140 corresponding to the second semiconductor pillar 102 into the insulating filling structure 150, the isolation between two adjacent gates 140 and the isolation between the gate 140 and its corresponding semiconductor pillar 110 can be achieved.

In this way, when the gate 140 and the bit line 120 are subsequently used to control the transistor structure to perform read, write, or erase operation on data, interference to a memory state of another transistor structure adjacent to this transistor structure can be avoided, thereby improving accuracy of controlling the transistor structure by the gate 140 and the bit line 120, and improving stability and reliability of the transistor structure and the semiconductor structure 100.

In addition, by illustration, in this example, the insulating filling structure 150 located between the gate 140 and its corresponding semiconductor pillar 110 may be used as a gate dielectric layer of the corresponding transistor structure.

Here, the insulating filling structure 150 may employ an insulating material, by illustration, the insulating material may include one or more of any suitable insulating material such as an oxide material (for example, silicon oxide), a nitride material (for example, silicon nitride), or an oxynitride material (for example, silicon oxynitride), which is not limited in the examples of the present disclosure.

Still referring to FIG. 4, in some examples, the insulating filling structure 150 includes an air gap 151, and the air gap 151 is disposed between the gate 140 corresponding to the first semiconductor pillar 101 and the gate 140 corresponding to the second semiconductor pillar 102.

In the present example, the air in the air gap 151 has a relatively small dielectric constant compared to some dielectrics (e.g., silicon oxide), for example, the dielectric constant of the air in the air gap 151 is about 0.25 times the dielectric constant of silicon oxide. Therefore, by forming the air gap 151 in the insulating filling structure 150, the isolation effect between two adjacent semiconductor pillars 110 may be improved, thereby improving the stability and reliability of the transistor structure and the semiconductor structure 100.

Still referring to FIG. 4, in some examples, the semiconductor structure 100 further includes a first dielectric layer 160. The first dielectric layer 160 is disposed on a side of the first sub-semiconductor pillar 111 away from the first isolation structure 130 along the second direction X.

In this example, based on the manufacture process of the semiconductor structure 100, by providing the first dielectric layer 160 on the side of the first sub-semiconductor pillar 111 away from the first isolation structure 130, the first sub-semiconductor pillar 111 on the semiconductor pillar 110 can be protected, thereby avoiding damage to the structure of the first sub-semiconductor pillar 111 in the manufacture process of the second sub-semiconductor pillar 112.

In this way, on the basis of protecting the size of the first sub-semiconductor pillar 111 in the second direction X, the size of the second sub-semiconductor pillar 112 in the second direction X can be reduced, thereby reducing the floating body effect of the transistor structure manufactured based on the second sub-semiconductor pillar 112, and improving the effect of electrical connection between the first sub-semiconductor pillar 111 and other devices, thereby reducing the off-state leakage current of the transistor structure, further prolonging the time of the DRAM cell where the transistor structure is located to retain data, and reducing the device loss of the semiconductor structure 100.

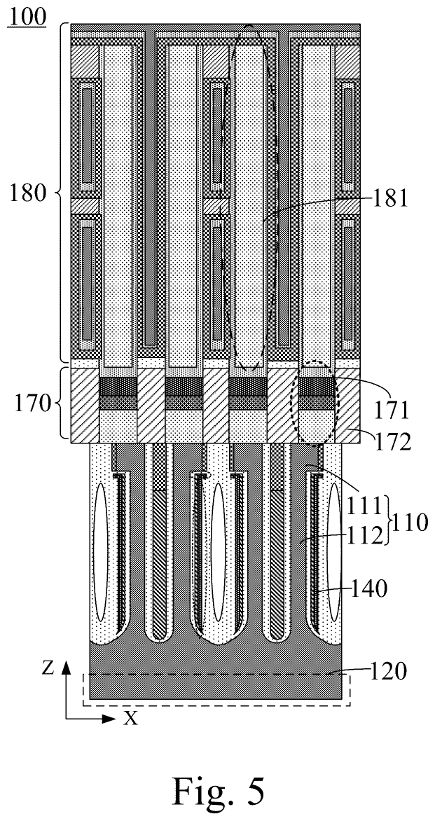

FIG. 5 is a schematic structural diagram of another semiconductor structure 100 provided by some examples of the present disclosure.

As shown in FIG. 5, in some examples, the semiconductor structure 100 further includes an interconnection layer 170, and the interconnection layer 170 is disposed on a side of the semiconductor pillar 110 away from the bit line 120 along the first direction Z.

Illustratively, a connection structure 171 may be disposed in the interconnection layer 170, in which the connection structure 171 may extend in the first direction Z, and an end of the connection structure 171 may be connected to an end of the first sub-semiconductor pillar 111 away from the second sub-semiconductor pillar 112, and the other end of the connection structure 171 may be connected to other device structures (for example, a capacitor unit).

In this way, the semiconductor pillar 110 may be led out by using the connection structure 171, thereby enabling signal transmission between the semiconductor pillar 110 and other device structures. The connection may include an electrical connection or a physical connection.

In some examples, the connection structure 171 may include a through silicon contact (TSC), a through silicon contact, or the like. In addition, in a case where the semiconductor pillar 110 includes a plurality of semiconductor pillars 110, the connection structure 171 may also include a plurality of connection structures 171, and shapes of the plurality of connection structures 171 may be the same or different, which is not limited in the examples of the present disclosure.

In addition, as a feasible implementation, in a case where the connection structure 171 may also include a plurality of connection structures 171, the interconnection layer 170 may further include an interlayer dielectric layer 172, and the plurality of connection structures 171 are disposed at intervals in the interlayer dielectric layer 172, so as to enable isolation between the plurality of connection structures 171, thereby improving reliability of the semiconductor structure.

Here, material of the connection structure 171 may include a conductive material, which includes, but is not limited to, W, Co, Cu, Al, doped silicon, silicide, or any combination thereof.

Still referring to FIG. 5, in some examples, the semiconductor structure 100 further includes a capacitor structure layer 180. The capacitor structure layer 180 is disposed on a side of the connection structure 171 away from the semiconductor pillar 110 along the first direction Z. The capacitor structure layer 180 includes a capacitor unit 181, and the capacitor unit 181 is connected to an end of the connection structure 171 away from the first sub-semiconductor pillar 111.

In this example, both ends of the semiconductor pillar 110 in the first direction Z are respectively connected to the bit line 120 and the capacitor unit 181, so as to form a 1T1C DRAM cell in combination with the gate 140 described above, and under the cooperation of the bit line 120 and the gate 140, charging and discharging of the capacitor unit 181 is controlled by using the semiconductor pillar 110, so as to enable the DRAM cell to perform read, write or erase operations on the data.

Illustratively, in a case where the connection structure 171 includes a plurality of connection structures 171, the capacitor unit 181 may also include a plurality of capacitor units 181, and each capacitor unit 181 is connected to one semiconductor pillar 110 through one connection structure 171, to form a DRAM cell array.

Based on the semiconductor structure 100 provided by some of the above examples, examples of the present disclosure further provide a manufacture method of the semiconductor structure 100, and the above described semiconductor structure 100 may be manufactured by the manufacture method of the semiconductor structure 100.

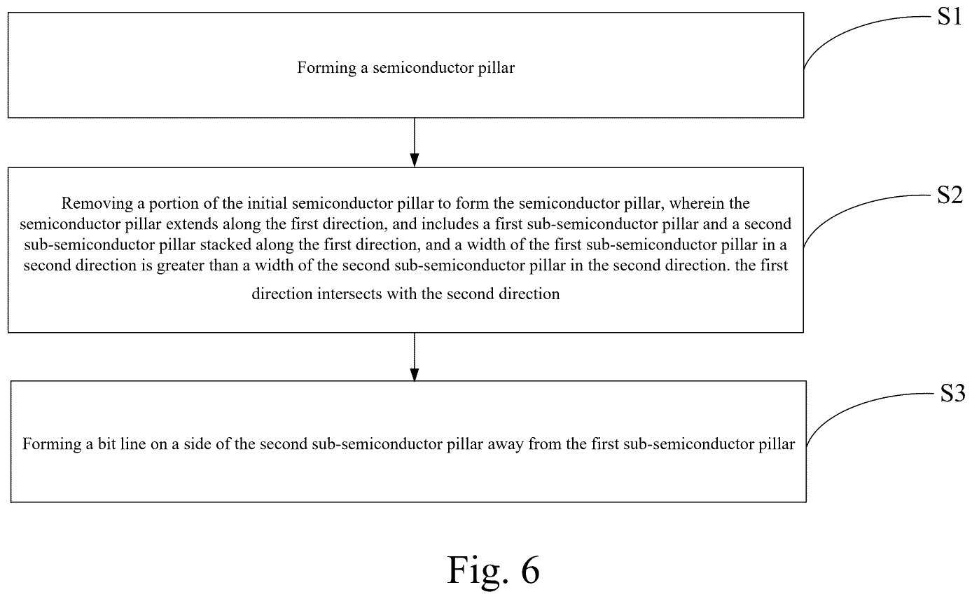

FIG. 6 is a flowchart of a manufacture method of a semiconductor structure 100 provided by some examples of the present disclosure.

As shown in FIG. 6, in some examples, the manufacture method of the semiconductor structure 100 includes the following operations S1 to S3.

S1: forming an initial semiconductor pillar.

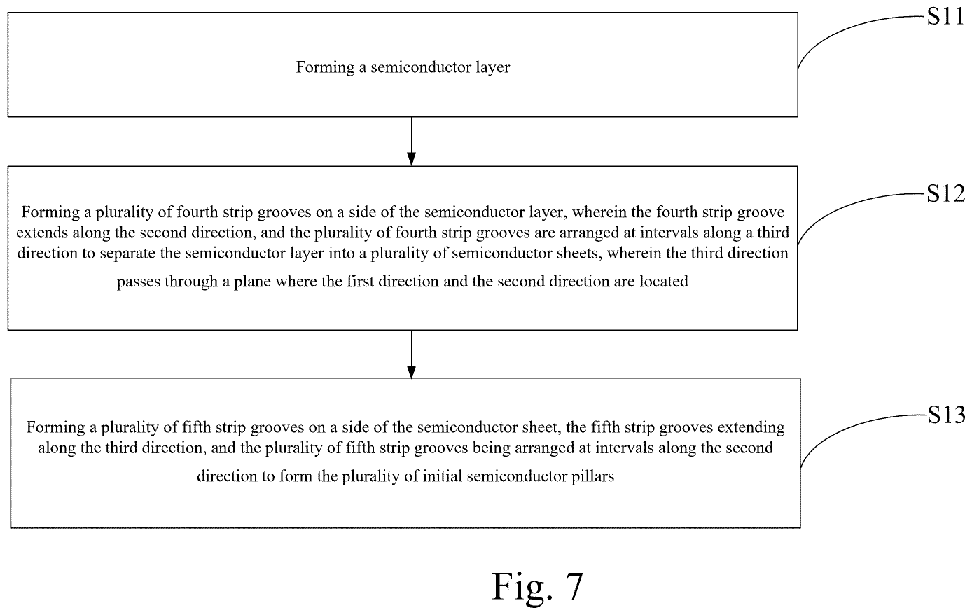

FIG. 7 is a flowchart of a method for manufacturing an initial semiconductor pillar 300 provided by some examples of the present disclosure.

As shown in FIG. 7, the above operation S1 may further include the following operations S11 to S13.

S11, forming a semiconductor layer.

Illustratively, the semiconductor layer 200 may be a monocrystalline silicon (Si) semiconductor layer, a monocrystalline germanium (Ge) semiconductor layer, a silicon-on-insulator (SOI) semiconductor layer, a germanium-on-insulator (GOI) semiconductor layer, or the like. Alternatively, the material of the semiconductor layer 200 may also be a compound semiconductor. For example, the semiconductor layer 200 may be a gallium arsenide (GaAs) semiconductor layer, an indium phosphide (InP) semiconductor layer, a silicon carbide (SiC) semiconductor layer, or the like. Alternatively, the semiconductor layer 200 may also be made of other semiconductor materials commonly used in the art, which is not limited in the examples of the present disclosure.

In this example, the manufacture of the initial semiconductor pillar 300 is described by using an example in which the material of the semiconductor layer 200 includes monocrystalline silicon.

S12, forming a plurality of fourth strip grooves on a side of the semiconductor layer, wherein the fourth strip groove extends along the second direction, and the plurality of fourth strip grooves are arranged at intervals along a third direction to separate the semiconductor layer into a plurality of semiconductor sheets. The third direction passes through a plane where the first direction and the second direction are located.

In the operation S12, a photoresist layer may be formed on a side surface of the semiconductor layer 200 by a suitable method such as static spin coating or dynamic spray coating, and the photoresist layer is patterned to obtain a first mask layer having a plurality of first openings.

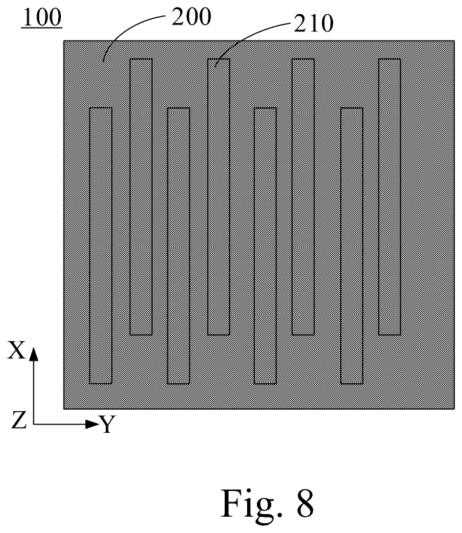

FIG. 8 is a schematic structural diagram of the semiconductor structure 100 corresponding to the manufacture method in FIG. 7.

As shown in FIG. 8, the semiconductor layer 200 is etched based on the first mask layer to form a plurality of semiconductor sheets 210. Illustratively, in this example, the semiconductor layer 200 may be etched by using any suitable process such as a self-aligned double patterning (SADP) process, to form the plurality of semiconductor sheets 210, and form a fourth strip groove between two adjacent semiconductor sheets 210. A height of the semiconductor sheet 210 in the first direction Z is lower than a height of the semiconductor layer 200 in the first direction Z.

Illustratively, the first direction Z may represent a direction in which the semiconductor sheet 210 and the remaining semiconductor layer 200 are stacked.

Each semiconductor sheet 210 may extend along the second direction X, the plurality of semiconductor sheets 210 may be arranged at intervals along the third direction Y, and in a feasible implementation, the plurality of semiconductor sheets 210 arranged at intervals along the third direction Y may be arranged in a staggered manner, so that in a subsequent manufacture process (for example, a bonding process), difficulty of leading out of the device structure manufactured based on the semiconductor sheet 210 may be reduced.

S13, forming a plurality of fifth strip grooves on a side of the semiconductor sheet, wherein the fifth strip groove extends along the third direction, and the plurality of fifth strip grooves are arranged at intervals along the second direction to form a plurality of initial semiconductor pillars.

A photoresist layer is formed on a side surface of the plurality of semiconductor sheets 210, and the photoresist layer is patterned to obtain a second mask layer having a plurality of second openings.

Illustratively, in the operation S13, the photoresist may also be applied in any suitable manner such as static spin coating or dynamic spray coating.

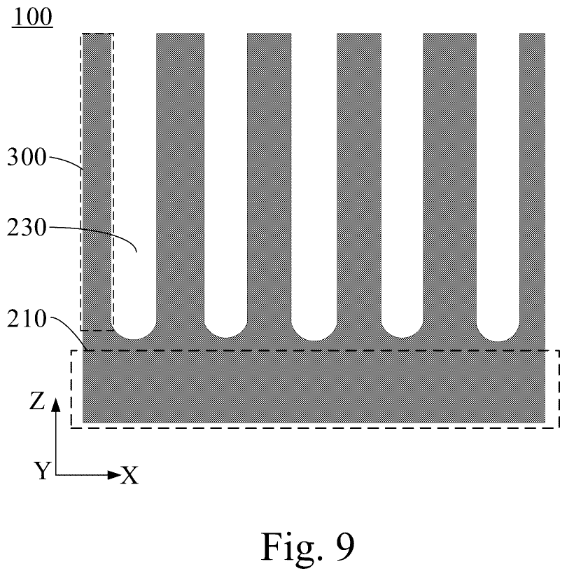

FIG. 9 is a schematic structural diagram of another semiconductor structure 100 corresponding to the manufacture method in FIG. 7.

As shown in FIG. 9, the semiconductor sheet 210 is etched based on the second mask layer to form the plurality of fifth strip grooves 230. Illustratively, in this example, the semiconductor sheet 210 may be etched by any suitable process such as a self-aligned reverse patterning (SARP) process, so as to form the plurality of fifth strip grooves 230, and a side of each semiconductor sheet 210 away from the semiconductor layer 200 may be divided into the plurality of initial semiconductor pillars 300 by the plurality of fifth strip grooves 230.

Each fifth strip groove 230 extends along the third direction Y, the plurality of fifth strip grooves 230 are arranged at intervals along the second direction X, and a depth of each fifth strip groove 230 in the first direction Z is lower than the height of the semiconductor sheet 210 in the first direction Z. In addition, the plurality of initial semiconductor pillars 300 manufactured are arranged in multiple rows and multiple columns, and the plurality of initial semiconductor pillars 300 in a row of the initial semiconductor pillars 300 are uniformly arranged along the second direction X.

As a feasible implementation, a channel structure of a row or column of transistor structures may be manufactured based on the plurality of initial semiconductor pillars 300 on one semiconductor sheet 210.

S2: removing a portion of the initial semiconductor pillar to form a semiconductor pillar. The semiconductor pillar extends along the first direction, and the semiconductor pillar includes a first sub-semiconductor pillar and a second sub-semiconductor pillar stacked along the first direction, and a width of the first sub-semiconductor pillar in the second direction is greater than a width of the second sub-semiconductor pillar in the second direction. The first direction intersects with the second direction.

Referring to FIG. 4 and FIG. 9, in the operation S2, the second sub-semiconductor pillar 112 may be manufactured by removing a portion of the initial semiconductor pillar 300, where the remaining initial semiconductor pillar 300 may form the first sub-semiconductor pillar 111, and then the first sub-semiconductor pillar 111 and the second sub-semiconductor pillar 112 are used to form the semiconductor pillar 110.

In a feasible implementation, the second sub-semiconductor pillar 112 may be used as a channel structure of a subsequently manufactured transistor structure. Based on this, in the operation S2, by reducing the width H2 in the second direction X of the initial semiconductor pillar 300 at the position of the second sub-semiconductor pillar 112, the thickness in the second direction X of the channel structure of the transistor structure manufactured based on the second sub-semiconductor pillar 112 can be reduced, thereby reducing the floating body effect of the transistor structure manufactured based on the second sub-semiconductor pillar 112, reducing the off-state leakage current of the manufactured transistor structure, and further prolonging the time for the DRAM cell formed by the transistor structure to retain data. In addition, reducing the width H2 of the second sub-semiconductor pillar 112 in the second direction X may enable further miniaturization of the size of the semiconductor structure 100.

In addition, in this example, by stacking the first sub-semiconductor pillar 111 on a side of the second sub-semiconductor pillar 112, the first sub-semiconductor pillar 111 may be used to enable the connection between the second sub-semiconductor pillar 112 and other device structures (e.g., a capacitor unit, etc.).

By setting the width H1 of the first sub-semiconductor pillar 111 in the second direction X to be greater than the width H2 of the second sub-semiconductor pillar 112 in the second direction X, the area of subsequently contact between the first sub-semiconductor pillar 111 and other device structures can be increased, thereby reducing the contact resistance between the first sub-semiconductor pillar 111 and other device structures, and reducing the device loss of the semiconductor structure 100. In addition, in this way, the first sub-semiconductor pillar 111 may also be used to reduce the difficulty of controlling the height of the gate in the first direction Z in the subsequent manufacture process of the gate, thereby improving the manufacturing accuracy.

In addition, based on the foregoing operation S1, in a scenario in which the plurality of initial semiconductor pillars 300 in a row of initial semiconductor pillars 300 manufactured are uniformly arranged, the plurality of first sub-semiconductor pillars 111 in a row of first sub-semiconductor pillars 111 manufactured in this operation S2 may also be uniformly arranged.

Since the plurality of capacitor units docked with the first sub-semiconductor pillars 111 arranged in multiple rows and multiple columns are mostly 6F² when the DRAM cell array is formed, the plurality of capacitor units and the plurality of first sub-semiconductor pillars 111 need to be connected through connection structures. Based on the situation that most of the connection structures are uniformly arranged, when the plurality of connection structures are docked with the plurality of semiconductor pillars, if a row of the first sub-semiconductor pillars 111 are arranged non-uniformly, an offset connection will occur between each connection structure and its docked first sub-semiconductor pillar 111, resulting in a smaller effective contact area between each connection structure and its docked semiconductor pillar, and further resulting in an increase in the contact resistance between the connection structure and its docked semiconductor pillar, or even an increase in the device loss of the semiconductor structure.

Based on this, in the case where the plurality of first sub-semiconductor pillars 111 in the row of first sub-semiconductor pillars 111 manufactured in the operation S2 are uniformly arranged, when the first sub-semiconductor pillar 111 is subsequently docked with a row of connection structures that are uniformly arranged, the offset degree between the connection structure and its docked first sub-semiconductor pillar 111 can be reduced, thereby increasing the effective contact area between the connection structure and its docked first sub-semiconductor pillar 111, thereby reducing the contact resistance between the connection structure and its docked first sub-semiconductor pillar 111, and further reducing the device loss of the semiconductor structure.

S3: forming a bit line on a side of the second sub-semiconductor pillar away from the first sub-semiconductor pillar.

Referring to FIG. 4 and FIG. 9, in operation S3, a conductive material may be deposited on a side of the second sub-semiconductor pillar 112 away from the first sub-semiconductor pillar 111 by using a thin film deposition process such as a chemical vapor deposition (CVD) process, a physical vapor deposition (PVD) process, an atomic layer deposition (ALD) process, or any combination thereof, to form the bit line 120.

Illustratively, the conductive material may include, but is not limited to, a combination of one or more of silicon germanium, tungsten, cobalt, copper, aluminum, and metal silicide, or other suitable materials may also be used. In this example, the material of the bit line 120 may be silicon germanium.

In some other examples, in the case where the initial semiconductor pillars 300 are manufactured based on the foregoing operation S1, the number of the manufactured initial semiconductor pillars 300 may be plural, and a portion of the initial semiconductor pillars 300 may be formed on one semiconductor sheet 210. In this case, the bit line 120 may be manufactured on a side surface of the semiconductor sheet 210 away from the plurality of initial semiconductor pillars 300, so that in practical applications, the bit line 120 may be controlled to select a plurality of transistor structures on one semiconductor sheet 210 connected to the bit line 120, and may be used to control the DRAM cell to perform operations of storing, writing or erasing data in combination with a subsequently manufactured gate.

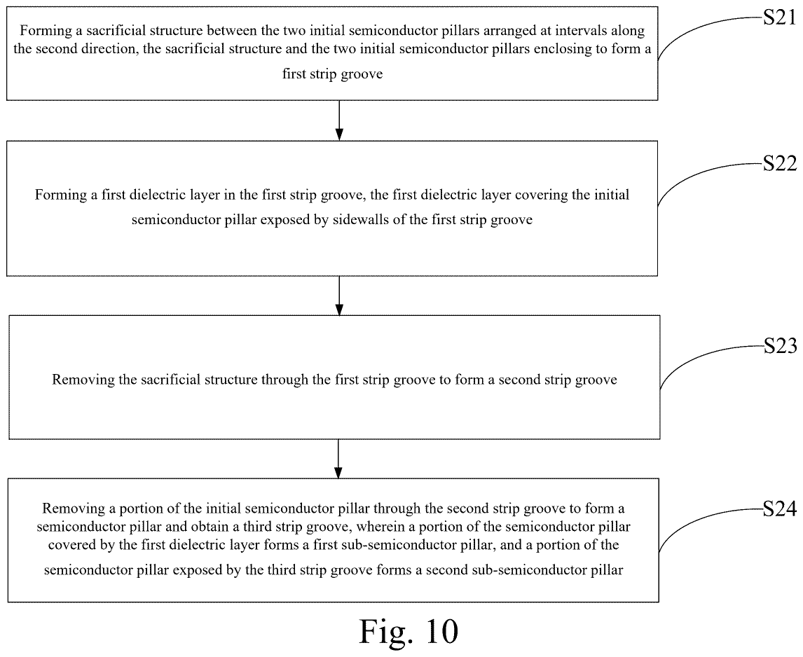

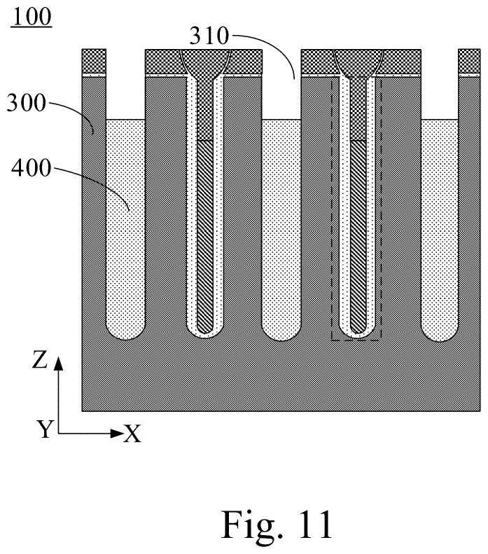

FIG. 10 is a flowchart of a manufacture method of a semiconductor structure 100 provided by some examples of the present disclosure, and FIG. 11 is a schematic structural diagram of the semiconductor structure 100 corresponding to the manufacture method in FIG. 10.

As shown in FIG. 10, in some examples, the above described operation S2 may further include the following operations S21 to S24.

S21, forming a sacrificial structure between the two initial semiconductor pillars arranged at intervals along the second direction, wherein a first strip groove is enclosed by the sacrificial structure and the two initial semiconductor pillars.

When the initial semiconductor pillars 300 are manufactured based on the foregoing operation S1, the number of the manufactured initial semiconductor pillars 300 may be plural. As shown in FIG. 11, in this scenario, in this operation S21, an insulating material may be deposited between the two initial semiconductor pillars 300 arranged at intervals along the second direction X by using a thin film deposition process such as a chemical vapor deposition process, a physical vapor deposition process, an atomic layer deposition process, or any combination thereof, to form a sacrificial structure 400.

A height of the sacrificial structure 400 in the first direction Z is less than a height of the initial semiconductor pillar 300 in the first direction Z. Based on this, the first strip groove 310 may be enclosed by the sacrificial structure 400 and its two adjacent initial semiconductor pillars 300.

Illustratively, a material of the sacrificial structure 400 may include any suitable insulating material, such as one or more of an oxide material (for example, silicon oxide), a nitride material (for example, silicon nitride), or an oxynitride material (for example, silicon oxynitride), which is not limited in the examples of the present disclosure. In this example, the material of the sacrificial structure 400 may be organic carbon.

Since the organic carbon has good fluidity, the filling difficulty can be simplified by using this material to manufacture the sacrificial structure 400. In addition, when the sacrificial structure 400 is made of the organic carbon material, in a subsequent process of removing the sacrificial structure 400, the difficulty of removing the sacrificial structure 400 may be reduced, and the residue of the sacrificial structure 400 after removal may be reduced.

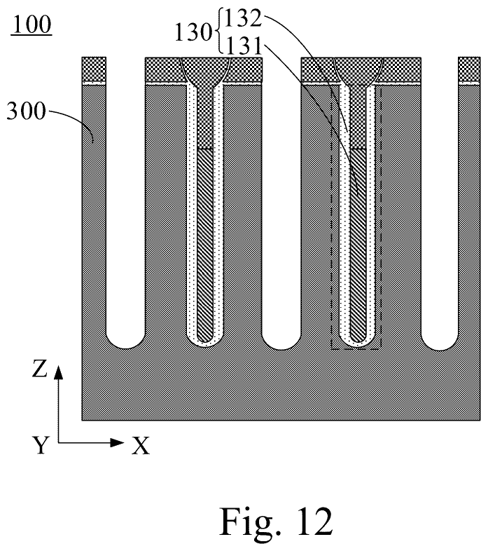

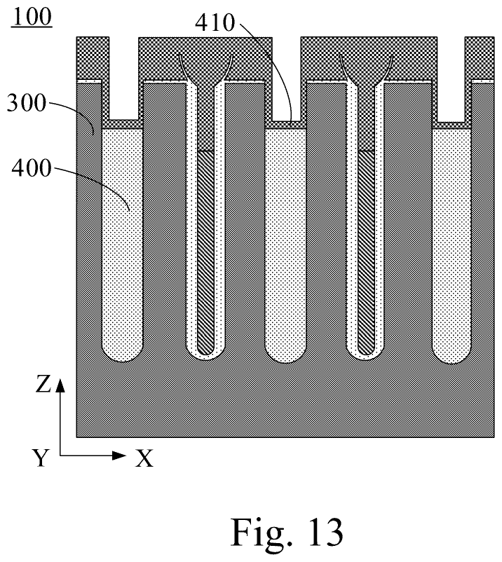

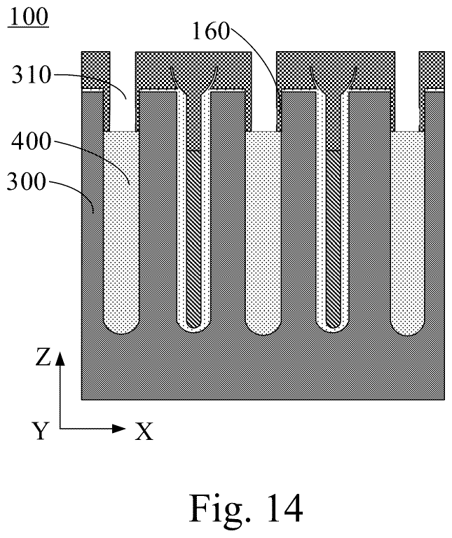

FIG. 12 is a schematic structural diagram of another semiconductor structure 100 corresponding to the manufacture method in FIG. 10, FIG. 13 is a schematic structural diagram of yet another semiconductor structure 100 corresponding to the manufacture method in FIG. 10, and FIG. 14 is a schematic structural diagram of yet another semiconductor structure 100 corresponding to the manufacture method in FIG. 10.

As shown in FIG. 11 and FIG. 12, in some examples, in the operation S21, before manufacturing the sacrificial structure 400, the manufacture method of the semiconductor structure may further include forming a first isolation structure 130 between the two initial semiconductor pillars 300 arranged at intervals along the second direction X. The first isolation structure 130 may include a first conductive structure 131 and an insulating structure 132, and illustratively, the insulating structure 132 may surround the first conductive structure 131, thereby improving the isolation effect of the first isolation structure 130 on the semiconductor pillars 110 of two adjacent columns of transistor structures.

In other examples, the process of manufacturing the first isolation structure 130 may also be performed after the process of manufacturing the sacrificial structure 400, wherein the specific order of the manufacture processes may be adjusted according to actual needs, which is not limited in the examples of the present disclosure.

S22, forming a first dielectric layer in the first strip groove, the first dielectric layer covering the initial semiconductor pillar exposed by the sidewall of the first strip groove.

In the operation S22, an insulating material may be deposited in the first strip groove 310 by using a thin film deposition process such as a chemical vapor deposition process, a physical vapor deposition process, an atomic layer deposition process, or any combination thereof, to form a first insulating portion.

Illustratively, a material of the first insulating portion may include any suitable insulating material such as one or more of an oxide material (for example, silicon oxide), a nitride material (for example, silicon nitride), or an oxynitride material (for example, silicon oxynitride), which is not limited in the examples of the present disclosure. In this example, the material of the first insulating portion may be silicon nitride.

A photoresist layer is formed on a side surface of the first insulating portion facing away from the sacrificial structure 400 by a suitable method such as static spin coating or dynamic spray coating, and the photoresist layer is patterned to obtain a fourth mask layer having a plurality of fourth openings.

A portion of the first insulating portion is removed through the fourth opening to form a dielectric layer 410 covering sidewalls and a bottom wall of the first strip groove as shown in FIG. 13.

Illustratively, the dielectric layer on the bottom wall of the first strip groove may be removed by using any suitable etching process such as dry etching or wet etching, to form the first dielectric layer 160 shown in FIG. 14.

S23, removing the sacrificial structure through the first strip groove to form a second strip groove.

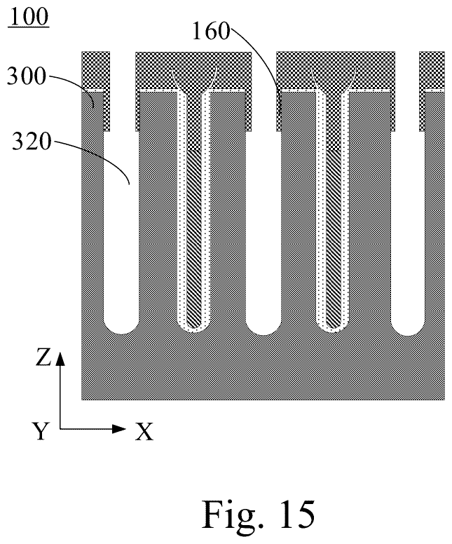

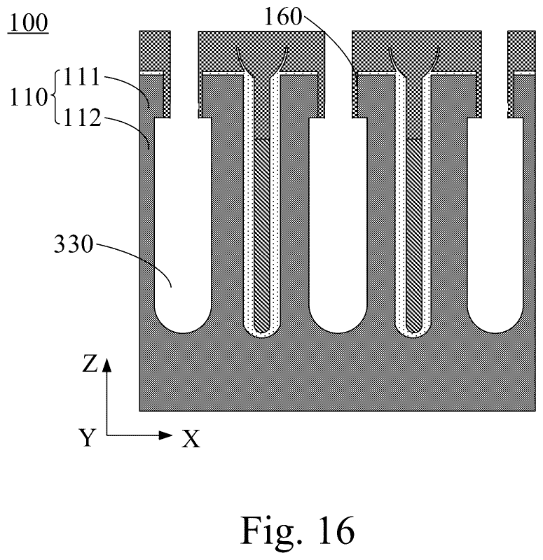

FIG. 15 is a schematic structural diagram of yet another semiconductor structure 100 corresponding to the manufacture method in FIG. 10. FIG. 16 is a schematic structural diagram of yet another semiconductor structure 100 corresponding to the manufacture method in FIG. 10.

As shown in FIG. 15, in the operation S23, the sacrificial structure 400 may be removed through the first strip groove 310 by any suitable etching process such as dry etching or wet etching to form the second strip groove 320.

The second strip groove 320 may expose the initial semiconductor pillar 300 at the position of the sacrificial structure 400.

S24, removing a portion of the initial semiconductor pillar through the second strip groove to form a semiconductor pillar, and obtain a third strip groove. A portion of the semiconductor pillar covered by the first dielectric layer forms a first sub-semiconductor pillar, and a portion of the semiconductor pillar exposed by the third strip groove forms a second sub-semiconductor pillar.

As shown in FIG. 15 and FIG. 16, in the operation S24, the initial semiconductor pillar 300 exposed by the second strip groove 320 may be etched through the second strip groove 320 by any suitable etching process such as dry etching or wet etching, so as to enable a thinning processing to the initial semiconductor pillar 300 at the position of the sacrificial structure, thereby forming the second sub-semiconductor pillar 112, and expanding the second strip groove 320 into the third strip groove 330. The initial semiconductor pillar 300 exposed by the second strip groove 320 is the initial semiconductor pillar 300 at the position of the sacrificial structure 400.

Since the first dielectric layer 160 covers a portion of sidewalls of the initial semiconductor pillar 300 in the foregoing operation 22, then in this operation S24, the initial semiconductor pillar 300 may be protect at the position of the first dielectric layer 160, so as to prevent the initial semiconductor pillar 300 at the position of the first dielectric layer 160 from being damaged by the etching process, thereby taking the initial semiconductor pillar 300 at the position of the first dielectric layer 160 as the first sub-semiconductor pillar 111 in the process of forming the second sub-semiconductor pillar 112.

In this way, the size of the first sub-semiconductor pillar 111 in the second direction X can be protected on the basis of thinning the initial semiconductor pillar 300 at the position of the sacrificial structure exposed by the second strip groove 320, so that the electrical connection effect between the first sub-semiconductor pillar 111 and other device structures can be improved on the basis of reducing the floating body effect of the transistor structure manufactured based on the second sub-semiconductor pillar 112, thereby reducing the off-state leakage current of the transistor structure, further prolonging the time of the DRAM cell where the transistor structure is located to retain data, and reducing the device loss of the semiconductor structure 100.

In some examples, the manufacture method of the semiconductor structure further includes the following operation S5.

S5, forming a gate on a side of the semiconductor pillar along the second direction through the third strip groove.

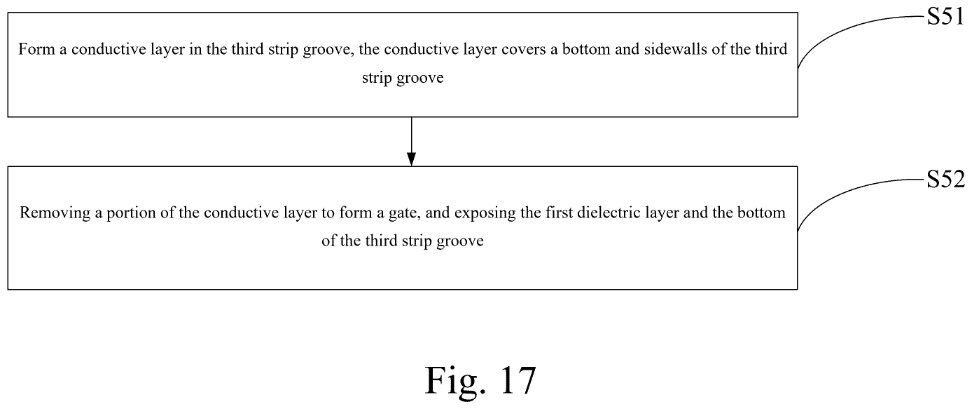

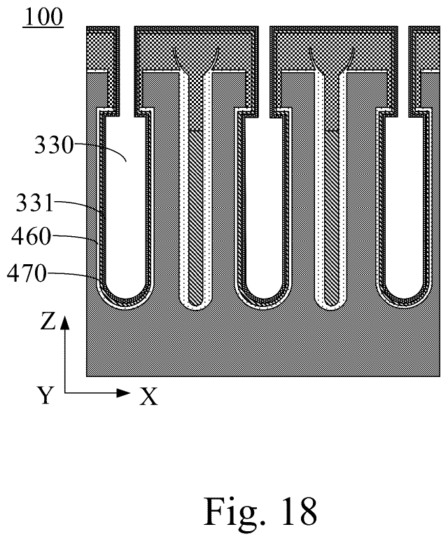

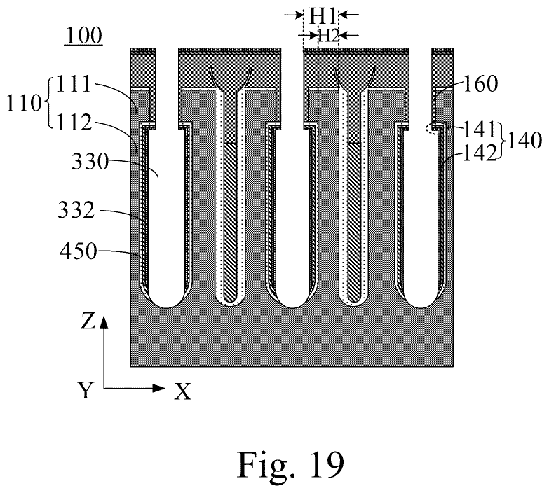

FIG. 17 is a flowchart of a manufacture method of a gate 140 provided by some examples of the present disclosure. FIG. 18 is a schematic structural diagram of a semiconductor structure 100 corresponding to the manufacture method in FIG. 17. FIG. 19 is a schematic structural diagram of another semiconductor structure 100 corresponding to the manufacture method in FIG. 17.

As shown in FIG. 17, in some examples, the above operation S5 may include the following operations S51 to S52.

S51: forming a conductive layer in the third strip groove, the conductive layer covering a bottom and sidewalls of the third strip groove.

As shown in FIG. 16 and FIG. 18, in this operation S51, a conductive material may be deposited in the third strip groove 330 by using a thin film deposition process such as a chemical vapor deposition process, a physical vapor deposition process, an atomic layer deposition process, or any combination thereof, to form a conductive layer 331.

Illustratively, a material of the conductive layer 331 may include, but is not limited to, a combination of one or more of silicon germanium, tungsten, cobalt, copper, aluminum, and metal silicide, or other suitable materials may also be used. In this example, the material of the conductive layer 331 may be tungsten.

S52: removing a portion of the conductive layer to form a gate, and exposing the first dielectric layer and the bottom of the third strip groove.

In this operation S52, a photoresist layer may be formed on a side surface of the conductive layer 331 facing away from the bottom of the third strip groove 330 by a suitable method such as static spin coating or dynamic spray coating, and the photoresist layer is patterned to obtain a fifth mask layer having a plurality of fifth openings.

The conductive layer 331 covering the bottom of the third strip groove 330 and the conductive layer 331 covering the first dielectric layer 160 are removed through the fifth opening, to form the gate 140 as shown in FIG. 19. The gate 140 may be correspondingly disposed on a side of the second sub-semiconductor pillar 112.

As a feasible implementation, the conductive layer 331 on the bottom of the third strip groove 330 and the conductive layer 331 covering the first dielectric layer 160 may be removed by any suitable etching process such as dry etching or wet etching, which is not limited in the examples of the present disclosure.

Still referring to FIG. 19, in the operation S52, by forming the gate 140 on a side of the semiconductor pillar 110, the transistor structure in the DRAM cell may be manufactured to complete. In addition, in practical applications, the transistor structure can be controlled to be on or off by using the gate 140, so as to control charging and discharging of the capacitor unit in the DRAM cell, thereby enabling the DRAM cell to perform read, write or erase operations on the data.

Illustratively, in this example, since the width H1 of the first sub-semiconductor pillar 111 in the second direction X is greater than the width H2 of the second sub-semiconductor pillar 112 in the second direction X, a surface of the first sub-semiconductor pillar 111 close to the first dielectric layer 160 and a surface of the second sub-semiconductor pillar 112 exposed by the third strip groove 330 are staggered in the first direction Z.

Based on this, the manufactured gate 140 may include a first sub-portion 141 and a second sub-portion 142 connected to the first sub-portion 141, the first sub-portion 141 is disposed along the second direction X on a side of the second sub-semiconductor pillar 112 exposed by the third strip groove 330, and the second sub-portion 142 is disposed along the first direction Z on a side of a position where the first sub-semiconductor pillar 111 protrudes from the second sub-semiconductor pillar 112.

With such an arrangement, it is possible to increase the facing area between the entire gate 140 and the semiconductor pillar 110, thereby improving the control accuracy of the gate 140 to the transistor structure manufactured based on the semiconductor pillar 110.

In addition, with such an arrangement, the leakage current of the transistor structure manufactured based on the semiconductor pillar 110 can be reduced by improving the control accuracy of the gate 140, thereby improving the time of the DRAM cell to retain data.

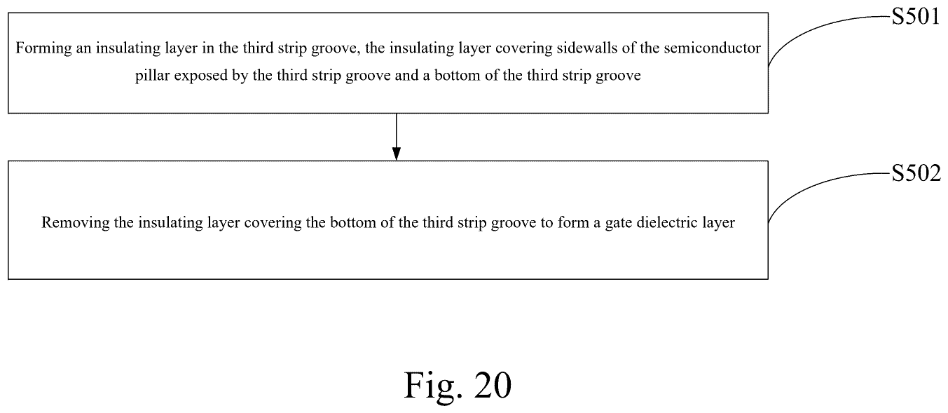

FIG. 20 is a flowchart of another manufacture method of a semiconductor structure 100 provided by some examples of the present disclosure.

As shown in FIG. 20, in some examples, in the manufacture process of the operation S5, the manufacture method of the semiconductor structure may further include the following operations: S501 to S502.

S501: forming an insulating layer in the third strip groove, the insulating layer covering sidewalls of the semiconductor pillar exposed by the third strip groove and the bottom of the third strip groove.

Still referring to FIG. 18, in the operation S501, an insulating layer 460 may be formed on the sidewalls of the semiconductor pillar exposed by the third strip groove and the bottom of the third strip groove by any suitable oxidation process such as wet oxidation or dry oxidation.

Illustratively, a material of the insulating layer 460 may include any suitable insulating material such as one or more of an oxide material (for example, silicon oxide), a nitride material (for example, silicon nitride), an oxynitride material (for example, silicon oxynitride), which is not limited in the examples of the present disclosure. In the example, the material of the insulating layer 460 may be silicon oxide.

S502: removing the insulating layer covering the bottom of the third strip groove to form a gate dielectric layer.

In the operation S502, a photoresist layer may be formed on a surface of the insulating layer 460 facing away from the sacrificial structure by a suitable method such as static spin coating or dynamic spray coating, and the photoresist layer is patterned to obtain a sixth mask layer having a plurality of sixth openings.

A portion of the insulating layer 460 is removed through the sixth opening to form the gate dielectric layer 450 covering the sidewall of the second sub-semiconductor pillar 112 exposed by the third strip groove 330 as shown in FIG. 19.

Illustratively, the second insulating portion may be removed by any suitable etching process such as dry etching or wet etching.

In this way, a side surface of the semiconductor pillar 110 close to the gate 140 can be planarized to meet the requirements of the semiconductor structure for high accuracy and high performance, and the gate dielectric layer 450, serving as a barrier, can effectively prevent impurities or pollutants in the environment from entering the semiconductor pillar 110, thereby improving the stability and reliability of the semiconductor pillar 110.

In addition, by forming the gate dielectric layer 450, isolation between the gate 140 and the semiconductor pillar 110 may also be achieved. In addition, since silicon oxide has stable electrical characteristics, the gate dielectric layer manufactured by the oxidation process would also have stable electrical characteristics, thereby improving the reliability and durability of the transistor structure subsequently manufactured on this basis.

In some examples, in the manufacture process of the above operation S5, the manufacture method of the semiconductor structure may further include the following operation S503.

S503: forming a conductive film in the third strip groove, in which the conductive film covers a bottom and sidewalls of the third strip groove.

Still referring to FIG. 18, in the operation S503, a conductive material may be deposited in the third strip groove 330 by using a thin film deposition process such as a chemical vapor deposition process, a physical vapor deposition process, an atomic layer deposition process, or any combination thereof, to form a second conductive structure 470.

Illustratively, a material of the second conductive structure 470 may include, for example, a combination of one or more of silicon germanium, tungsten, cobalt, copper, aluminum, and metal silicide, or other suitable materials may also be used. In the operation S503, the material of the second conductive structure 470 may be titanium nitride.

A photoresist layer is formed on a side surface of the second conductive structure 470 away from the bottom of the third strip groove 330 by a suitable method such as static spin coating or dynamic spray coating, and the photoresist layer is patterned to obtain a seventh mask layer having a seventh opening.

A portion of the second conductive structure 470 is removed through the seventh opening to form a conductive film 332 covering the bottom and sidewalls of the third strip groove 330 as shown in FIG. 19.

Illustratively, the portion of the conductive structure may be removed by any suitable etching process such as dry etching or wet etching, which is not limited in the examples of the present disclosure.

In this way, the remaining of the conductive film 332 can be utilized to prevent the metal material of the gate 140 from diffusing, and titanium nitride has good adhesion, which is advantage to improve the stability of the structure of the gate 140.

In some implementations, the conductive layer 331 in the above operation S51 may be formed on the side of the conductive film 332 away from the semiconductor pillar 110, and the etching of the second conductive structure 470 in this operation S503 may be completed in the same process as the etching of the conductive layer 331 in the above operation S52 and the etching of the insulating layer 460 in the above operation S502, thereby simplifying the manufacture process and improving the manufacturing efficiency of the semiconductor structure 100.

Still referring to FIG. 19, in some examples, in the manufacture process of the above operation S5, in a case where the manufacture of the gate 140 is completed, the third strip groove 330 further has a cavity structure.

As a feasible implementation, in this example, an insulating material may be deposited in the cavity structure of the third strip groove 330 by using a thin film deposition process such as chemical vapor deposition, physical vapor deposition, atomic layer deposition, or any combination thereof, to form the second insulating portion.

Illustratively, an insulating material of the second insulating portion may include one or more of an oxide material (for example, silicon oxide), a nitride material (for example, silicon nitride), and an oxynitride material (for example, silicon oxynitride).

In this example, the material of the second insulating portion is silicon oxide, and in the case where the material of the second insulating portion is silicon oxide, the second insulating portion and the gate dielectric layer may be an integral structure. That is, there is no obvious boundary between the second insulating portion and the gate dielectric layer in structure. Based on this, the second insulating portion and the gate dielectric layer may form an insulating filling structure 150 as shown in FIG. 4.

In this way, in the case where the number of the semiconductor pillars 110 is arranged in a plurality of rows and a plurality of columns, the isolation between two adjacent semiconductor pillars 110 and the isolation between the gates 140 corresponding to the two adjacent semiconductor pillars 110 may be achieved by using the insulating filling structure 150, so that when the gate 140 is used to control the transistor structure to perform read, write, or erase operations on the data, it is avoided that the gate 140 interferes with the memory state of the adjacent transistor structure, thereby improving the accuracy of controlling the transistor structure by the gate 140, and improving the stability and reliability of the transistor structure and the semiconductor structure 100.

In addition, referring to FIG. 19, in some examples, in the process of manufacturing the second insulating portion, the cavity structure of the third strip groove 330 may not be completely filled with an insulating material, so as to form the air gap 151 shown in FIG. 4 in the second insulating portion, wherein the air gap may be disposed between the gates 140 corresponding to the two adjacent semiconductor pillars 110.

In the present example, the air in the air gap 151 has a relatively small dielectric constant compared to some dielectrics (e.g., silicon oxide). Therefore, by forming the air gap 151 in the second insulating portion, the effect of isolation between the two adjacent semiconductor pillars 110 may be improved, thereby improving the stability and reliability of the transistor structure and the semiconductor structure 100.

In some examples, in the manufacture process of the first insulating portion in the above operation S22, or in the manufacture process of the second insulating portion described above, the deposited insulating material may be redundant, and the redundant insulating material may cover a side surface of the first sub-semiconductor pillar away from the second sub-semiconductor pillar. Therefore, in the examples of the present disclosure, after the manufacture of the insulating filling structure is completed, the redundant material may be polished by chemical mechanical polishing (CMP) to remove excess insulating material, thereby exposing the side surface of the first sub-semiconductor pillar away from the second sub-semiconductor pillar, and obtaining the semiconductor structure 100 shown in FIG. 4.

In this way, an end of the first sub-semiconductor pillar away from the second sub-semiconductor pillar may be connected to other device structures (for example, a connection structure) subsequently manufactured, so that connections between the second sub-semiconductor pillar and other device structures subsequently manufactured may be achieved by the first sub-semiconductor pillar.

In addition, since the size of the first sub-semiconductor pillar in the second direction is greater than the size of the second sub-semiconductor pillar in the second direction, in this example, by using the connections between the first sub-semiconductor pillar and other device structures subsequently manufactured, a contact resistance between the first sub-semiconductor pillar and other device structures can be reduced, thereby reducing a device loss of the semiconductor structure.

The above is only a specific implementation of the present disclosure, but the protection scope of the present disclosure is not limited thereto. Any changes or substitutions that can be easily thought of by a person skilled in the art within the technical scope disclosed in the present disclosure should be included in the protection scope of the present disclosure. Therefore, the protection scope of the present disclosure should be based on the protection scope of the claims.

What is claimed is:

1. A semiconductor structure, comprising:
a semiconductor pillar extending along a first direction, the semiconductor pillar comprising a first sub-semiconductor pillar and a second sub-semiconductor pillar stacked along the first direction, wherein a width of the first sub-semiconductor pillar in a second direction is greater than a width of the second sub-semiconductor pillar in the second direction, the first direction intersecting with the second direction; and
a bit line disposed on a side of the second sub-semiconductor pillar away from the first sub-semiconductor pillar along the first direction.

2. The semiconductor structure according to claim 1, further comprising:
a first isolation structure disposed on a side of the semiconductor pillar along the second direction,
wherein the first sub-semiconductor pillar comprises a first surface and a second surface disposed opposite to each other along the second direction, and the first surface is closer to the first isolation structure than the second surface,
wherein the second sub-semiconductor pillar comprises a third surface and a fourth surface disposed opposite to each other along the second direction, and the third surface is closer to the first isolation structure than the fourth surface, and
wherein a distance between the second surface and the first isolation structure in the second direction is greater than a distance between the fourth surface and the first isolation structure in the second direction.

3. The semiconductor structure according to claim 1, wherein the width of the second sub-semiconductor pillar in the second direction is greater than or equal to 5 nm and less than or equal to 10 nm.

4. The semiconductor structure according to claim 1, wherein a ratio of the width of the first sub-semiconductor pillar in the second direction to the width of the second sub-semiconductor pillar in the second direction is greater than or equal to 1.2 and less than or equal to 2.2.

5. The semiconductor structure according to claim 2, further comprising:
a gate disposed along the second direction on a side of the second sub-semiconductor pillar away from the first isolation structure.

6. The semiconductor structure according to claim 5, wherein the first sub-semiconductor pillar further comprises a fifth surface and a sixth surface disposed opposite to each other along the first direction, and the fifth surface is closer to the second sub-semiconductor pillar than the sixth surface, and
wherein the gate comprises a first sub-portion and a second sub-portion connected to the first sub-portion, the first sub-portion is disposed along the second direction on a side of the second sub-semiconductor pillar away from the first isolation structure, and the second sub-portion is disposed along the first direction on a side of the fifth surface.

7. The semiconductor structure according to claim 5, wherein the semiconductor structure comprises a plurality of semiconductor pillars comprising the semiconductor pillar, the plurality of semiconductor pillars being arranged in multiple rows and multiple columns,
wherein second surfaces of a column of first sub-semiconductor pillars of the plurality of semiconductor pillars are disposed on a same side of the column of the first sub-semiconductor pillars in the second direction, and
wherein, in two adjacent columns of the first sub-semiconductor pillars, the second surfaces of a first column of the first sub-semiconductor pillars are disposed on a first side of the first column of the first sub-semiconductor pillars in the second direction, and the second surfaces of a second column of the first sub-semiconductor pillars are disposed on a second side of the second column of the first sub-semiconductor pillars in the second direction.

8. The semiconductor structure according to claim 7, wherein the semiconductor structure comprises a plurality of gates comprising the gate, the plurality of gates being arranged in multiple rows and multiple columns,
wherein one of the plurality of gates is correspondingly disposed on a side of one of the plurality of semiconductor pillars in the second direction, and a column of the plurality of gates is disposed on a same side of a column of the plurality of semiconductor pillars in the second direction, and
wherein a row of semiconductor pillars comprises a first semiconductor pillar and a second semiconductor pillar that are adjacent to each other, the first semiconductor pillar and the second semiconductor pillar are arranged at intervals along the second direction, a gate corresponding to the first semiconductor pillar and a gate corresponding to the second semiconductor pillar are disposed between the first semiconductor pillar and the second semiconductor pillar, and the first isolation structure is disposed along the second direction on a side of the first semiconductor pillar away from the gate corresponding to the first semiconductor pillar.

9. The semiconductor structure according to claim 8, wherein a distance in the second direction between a corresponding first sub-semiconductor pillar of the first semiconductor pillar and a corresponding first sub-semiconductor pillar of the second semiconductor pillar is same as a width of the first isolation structure in the second direction.

10. The semiconductor structure according to claim 8, further comprising:
an insulating filling structure disposed between the first semiconductor pillar and the second semiconductor pillar,
wherein the gate corresponding to the first semiconductor pillar and the gate corresponding to the second semiconductor pillar are both embedded in the insulating filling structure.

11. The semiconductor structure according to claim 10, wherein the insulating filling structure comprises an air gap between the gate corresponding to the first semiconductor pillar and the gate corresponding to the second semiconductor pillar.

12. The semiconductor structure according to claim 2, further comprising:
a first dielectric layer disposed along the second direction on a side of the first sub-semiconductor pillar away from the first isolation structure.

13. The semiconductor structure according to claim 1, further comprising:
a connection structure disposed along the first direction on a side of the semiconductor pillar away from the bit line, wherein the connection structure is connected to an end of the first sub-semiconductor pillar away from the second sub-semiconductor pillar.

14. The semiconductor structure according to claim 13, further comprising:
a capacitor structure layer disposed on a side of the connection structure away from the semiconductor pillar along the first direction, wherein the capacitor structure layer comprises a capacitor unit connected to an end of the connection structure away from the first sub-semiconductor pillar.

15. A manufacture method of a semiconductor structure, comprising:
forming an initial semiconductor pillar;
removing a portion of the initial semiconductor pillar to form a semiconductor pillar, wherein the semiconductor pillar extends along a first direction and comprises a first sub-semiconductor pillar and a second sub-semiconductor pillar stacked along the first direction, a width of the first sub-semiconductor pillar in a second direction is greater than a width of the second sub-semiconductor pillar in the second direction, and the first direction intersects with the second direction; and
forming a bit line on a side of the second sub-semiconductor pillar away from the first sub-semiconductor pillar along the first direction.

16. The manufacture method according to claim 15, wherein removing the portion of the initial semiconductor pillar to form the semiconductor pillar comprises:
forming a sacrificial structure between two initial semiconductor pillars arranged at intervals along the second direction, wherein a first strip groove is enclosed by the sacrificial structure and the two initial semiconductor pillars;
forming a first dielectric layer in the first strip groove, wherein the first dielectric layer covers the initial semiconductor pillar exposed by sidewalls of the first strip groove;
removing the sacrificial structure through the first strip groove to form a second strip groove; and
removing a portion of the initial semiconductor pillar through the second strip groove to form the semiconductor pillar and obtain a third strip groove, wherein a portion of the semiconductor pillar covered by the first dielectric layer forms the first sub-semiconductor pillar, and a portion of the semiconductor pillar exposed by the third strip groove forms the second sub-semiconductor pillar.

17. The manufacture method according to claim 16, further comprising:
forming, through the third strip groove, a gate on a side of the semiconductor pillar along the second direction.

18. The manufacture method according to claim 17, wherein forming the gate on the side of the semiconductor pillar along the second direction comprises:
forming a conductive layer in the third strip groove, wherein the conductive layer covers a bottom and sidewalls of the third strip groove; and
removing a portion of the conductive layer to form the gate, and exposing the first dielectric layer and the bottom of the third strip groove.

19. The manufacture method according to claim 17, further comprising:
forming an insulating layer in the third strip groove, wherein the insulating layer covers sidewalls of the semiconductor pillar exposed by the third strip groove and a bottom of the third strip groove; and
removing the insulating layer covering the bottom of the third strip groove to form a gate dielectric layer.

20. A memory system comprising:
a semiconductor structure comprising a semiconductor pillar and a bit line, the semiconductor pillar extending in a first direction and comprising a first sub-semiconductor pillar and a second sub-semiconductor pillar stacked along the first direction, wherein a width of the first sub-semiconductor pillar in a second direction is greater than a width of the second sub-semiconductor pillar in the second direction, the first direction intersects with the second direction, and the bit line is disposed on a side of the second sub-semiconductor pillar away from the first sub-semiconductor pillar along the first direction; and
a controller coupled to the semiconductor structure and configured to control the semiconductor structure to store data.
